(19) United States
(12) Patent Application Publication
(10) Pub. No.: US 2006/0113584 A1
(43) Pub. Date: Jun. 1, 2006

(54) Manufacturing method of a semiconductor device

(75) Inventors: Mikio Fukuda, Tatebayashi-Shi (JP); Tatsuya Fujishima, Ora-gun (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/267,582

(22) Filed: Nov. 7, 2005

(30) Foreign Application Priority Data
Nov. 8, 2004 (JP) 2004-324019

(51) Int. Cl. H01L 29/788

(52) U.S. Cl. 257/316

(57) ABSTRACT

The first polysilicon film is formed on the semiconductor substrate with the gate insulation film between them. The second silicon nitride film with the first opening is further formed and the first polysilicon film is etched using the second silicon nitride film as a mask. Then, the spacer film with the second opening is formed at the first opening. The oxidation prevention layer is formed through the first anneal processing performed in ammonia atmosphere. Then, the source region, the source line, the source line cap film, the floating gate, the tunnel insulation film, the control gate, and the drain region are formed.

### CROSS-REFERENCE OF THE INVENTION

This invention is based on Japanese Patent Application No. 2004-324019, the content of which is incorporated herein by reference in its entirety.

### BACKGROUND OF THE INVENTION

1. Field of Invention

This invention relates to a manufacturing method of a semiconductor device, especially to a manufacturing method of a semiconductor device with a non-volatile semiconductor memory device.

2. Description of Related Art

An electrically erasable and programmable read only memory (referred to as EEPROM hereinafter) has been widely used in recent years as its applicable field such as cellular phone and digital camera has been expanding.

The EEPROM uses a binary or multiple value digital data by determining if a predetermined charge is stored in a floating gate or not. Then, it reads out the digital data by detecting the change of the conduction in channel region corresponding to the charge. There are two types of EEPROM, a stacked-gate type and a split-gate type.

FIG. 30 is a cross sectional view of a conventional semiconductor device with a split-gate type EEPROM memory cell, showing the configuration of one memory cell. An n+ type drain region 102 and an n+ type source region 103 are disposed with a predetermined distance between them, where a channel region 104 is also formed, on a P type semiconductor substrate 101. A floating gate 106 is formed above a part of the channel region 104 and a part of the source region 103 with a gate insulation film 105 inserted in the middle. A thick silicon oxide film 107 formed through a selective oxidation method is disposed on the floating gate 106.

A tunnel insulation film 108 is disposed to cover the side of the floating gate 106 and a part of the surface of the thick silicon oxide film 107. A control gate 109 is formed on the tunnel insulation film 108 and the channel region 104.

The operation of the memory cell with the configuration described above is as follows. A predetermined voltage is applied to the control gate 102 and the source region 103 (for example, 0V to the p type semiconductor substrate, 2V to the control gate 102, and 10V to the source region 103), letting electric current going through the channel region 104 when a digital data is written in. Channel hot electrons (CHE) are injected into the floating gate 106 through the gate insulation film 105. The channel hot electrons injected into the floating gate 106 are stored as electric charge in the floating gate 106.

The capacitance coupling between the floating gate 106 and the source region 103 is much larger than the capacitance coupling between the control gate 109 and the floating gate 106. Therefore, the voltage of the floating gate 106 increases because of the voltage given to the source region 103, improving the injection efficiency of the channel hot electron to the floating gate 106.

The drain region 102 and the source region 103 are earthed, feeding a predetermined voltage (for example, 13V) to the control gate 109, when a digital data is deleted. Fowler-Nordheim tunneling current (FN) goes through the tunnel insulation film 108, pulling the electrons stored in the floating gate 106 into the control gate 109. Since a peak portion 106A, where an electric field concentration is formed, is disposed at an end of the floating gate 106, it is possible to have the Fowler-Nordheim tunneling current go through with a relatively low control gate voltage, achieving an efficient data deletion.

A predetermined voltage is applied to the control gate 109 and the drain region 102 (for example, 2V) when the data stored in the memory cell is read out. A channel current goes through according to the electric charge of the electron stored in the floating gate 106 and a current sense amplifier detects this channel current, reading out the stored data.

The split-gate type EEPROM enables the efficient programming as well as the data deletion. However, the memory cell design requires some countermeasure for the possible mask displacement because the control gate 109 and floating gate 106, and the control gate 109 and the thick silicon oxide film 107 are not disposed in self-aligned manner. This fact limits the minimization of the size of the split-gate type EEPROM memory cell.

Then, a self-aligned split-gate type EEPROM has been developed. FIG. 31 is a cross-sectional view of another conventional semiconductor device with a self-aligned spilt gate type EEPROM memory cell. A first memory cell MC10 and a second memory cell MC 20 are symmetrically disposed with the source region 203 in the center, as shown in the figure.

The configuration of the first memory cell MC10 will be explained below. The second memory cell has the identical configuration. An n+ type drain region 202 and an n+ source region 203 are disposed with a predetermined space between them, where a channel region 204 is formed, on a P type semiconductor substrate 201. A floating gate 206 is formed on a part of the channel region 204 and a part of the source region 203 with a gate insulation film 205 in the middle. A spacer film 207 that is made of oxide silicon is disposed in a self-aligned manner on the floating gate 206.

A tunnel insulation film 208 is formed covering the side surface and a part of the upper surface of the floating gate 206. A control gate 209 is formed in self-aligned manner to the side-wall of the spacer film 207. That is, the control gate 209 is disposed along with the side-wall of the spacer film 207 on a part of the channel region 204.

The operation of the first memory cell MC 10 is the same as that of the EEPROM memory cell of FIG. 30. In the first and second memory cells MC 10 and MC20, the control gate 209 is formed in such way that it is self-aligned to the floating gate 206 and the spacer film 207. Also, a source line 210 makes contact with a source region 203 in a self-aligned manner. The self-aligned split-gate type EEPROM enables the further reduction of the size of the memory cell.

The technology related to the self-aligned split-gate type EEPROM memory cell mentioned above is disclosed, for example, in Japanese Patent No. 3481934 and Japanese Patent Application Publication No. 2003-124361.

FIG. 32 is also a cross sectional view of another semiconductor device with a split-gate type EEPROM memory cell. A source line cap film 211 is formed on the source line 210 through thermal oxidation treatment to the source line 210 in the split-gate type EEPROM memory cell, as seen from FIG. 32. Oxidation seeds spread to the joint surface between the gate insulation film 205 and the floating gate 206 and to the further end of the floating gate 206 during the thermal oxidation treatment, oxidizing a part of the floating gate 206.

The oxidized part of the floating gate 206A acts as a capacitance insulation film, deteriorating the coupling property, which may cause the malfunction of the memory cell. That is, the capacitance coupling between the floating gate 206 and the source region 203 is reduced, causing the deteriorated reliability and the yield rate of the memory cell.

### SUMMARY OF THE INVENTION

The invention provides a method of manufacturing a semiconductor device. The method includes providing a semiconductor substrate having a first insulation film formed on its surface, forming a first semiconductor layer on the first insulation film, and forming a mask layer on the first semiconductor layer. The mask layer has an opening to expose part of the first semiconductor layer. The method also includes performing an etching on the exposed first semiconductor layer using the mask layer as an etching mask, forming a spacer on a sidewall of the opening, etching the first semiconductor layer and the first insulation film using the spacer as an etching mask to expose part of the semiconductor substrate, forming a first oxidation prevention layer containing nitrogen along a sidewall of the spacer and an edge of the etched first semiconductor layer, forming a source line in the opening, forming a cap film on the source line by performing an oxidation on the source line, forming a floating gate made of the first semiconductor layer by removing at least part of the mask layer and part of the first semiconductor layer, forming a tunnel insulating film on the spacer, the source cap film and the floating gate, forming a second semiconductor layer on the tunnel insulating film, and forming a control gate by removing part of the second semiconductor layer.

### BRIEF DESCRIPTION OF THE DRAWINGS

FIG. 1 is a plan view of an embodiment of the semiconductor device of this invention.

FIGS. 2 to 19 are cross sectional views showing a manufacturing method of the first embodiment of the semiconductor device of this invention.

FIG. 20 is a cross sectional view showing the semiconductor device and its manufacturing method of the first embodiment of this invention.

FIGS. 21 to 28 are cross sectional views showing a manufacturing method of the second embodiment of the semiconductor device of this invention.

FIG. 29 is a cross sectional view showing the semiconductor device and its manufacturing method of the second embodiment of this invention.

FIGS. 30 to 32 are cross sectional views showing conventional semiconductor devices.

### DETAILED DESCRIPTION OF THE INVENTION

A manufacturing method of the first embodiment of a semiconductor device of this invention will be explained by referring to figures.

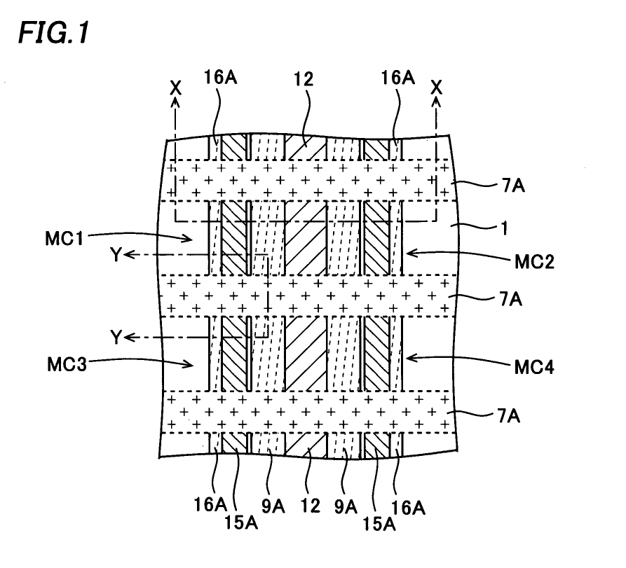

FIG. 1 is a plan view showing the configuration of an embodiment of a semiconductor device of this invention. FIG. 1 is a plan view showing the semiconductor device from the surface of a semiconductor substrate 10, and a part of configuration (a semiconductor substrate 1, a STI layer 7A, a spacer film 9A, source line 12) is shown through the structure. Here, a STI layer 7A is an element separation layer with a configuration known as the shallow trench isolation (referred to as STI, hereinafter).

FIG. 20 is a cross sectional view showing the semiconductor device and its manufacturing method of this invention. It shows the cross sections along with the X-X line and the Y-Y line in FIG. 1. The left side figure in FIG. 20 shows the cross section along with the X-X line, and the right side figure in FIG. 20 shows the cross section along with the Y-Y line.

The STI layers 7A, which are element separation layers, are formed with a predetermined depth and a predetermined distance from each other on a semiconductor substrate 1 with a gate insulation film 2 being formed on the surface, as shown in FIGS. 1 and 20. A plurality of memory cells that is a non-volatile semiconductor memory device is disposed between the STI layers 7A with regularity. FIG. 1 only shows the memory cells MC1, MC2, MC3, and MC4 and FIG. 20 only shows the memory cells MC1 and MC2 among a plurality of memory cells. The memory cells MC3 and MC4 have the identical configuration as that of the memory cells MC1 and MC2.

The memory cells MC1, MC2, MC3, and MC4 are split-gate type EEPROM memory cell with the configuration described below. A floating gate 3A are formed on the semiconductor substrate 1 with the gate insulation film 2A between them. A spacer film 9A is disposed on the floating gate 3A. An oxidation prevention layer 9N is formed at the side of the spacer film 9A and the floating gate 3A.

A control gate 15A is also formed adjacent to the floating gate 3A with a tunnel insulation film 14A in the middle. A source region 11 is formed on the semiconductor substrate 1 between the two floating gates 3A, and a drain region 17 is formed on the semiconductor substrate 1 adjacent to the control gate 15A. A source line 12 is disposed on the source region 11. A source line cap film 13 is formed on the source line 12.

Next, the manufacturing method in which the split-gate type EEPROM memory cell is formed in a self-aligned manner on the semiconductor substrate will be explained.

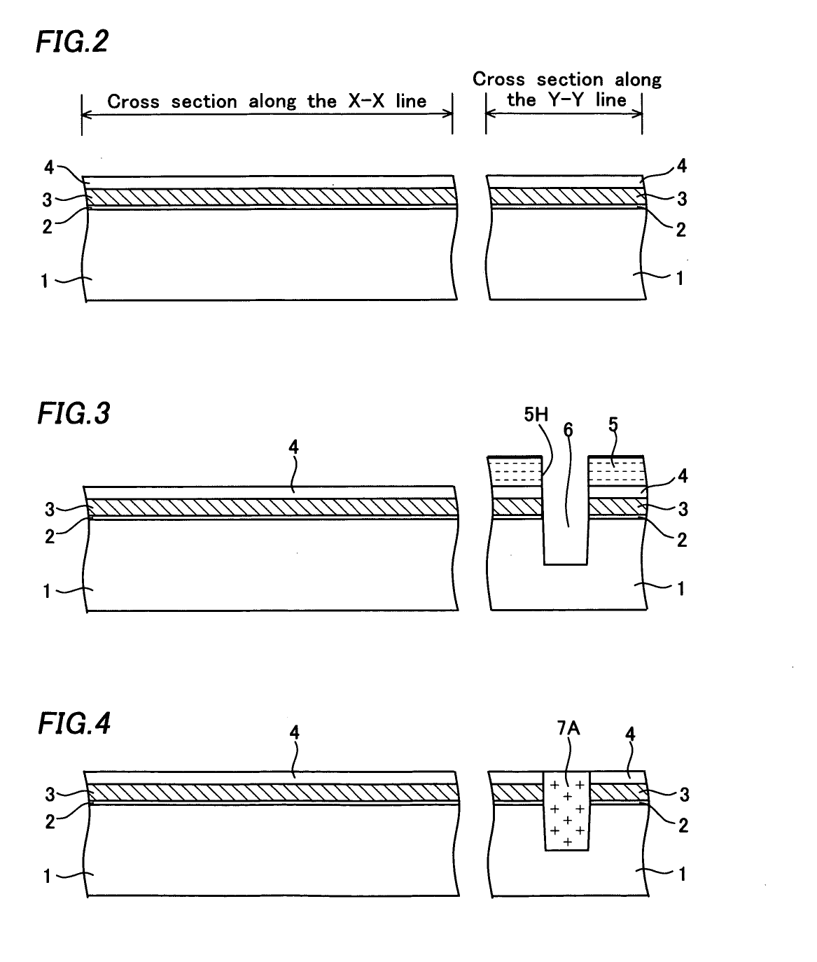

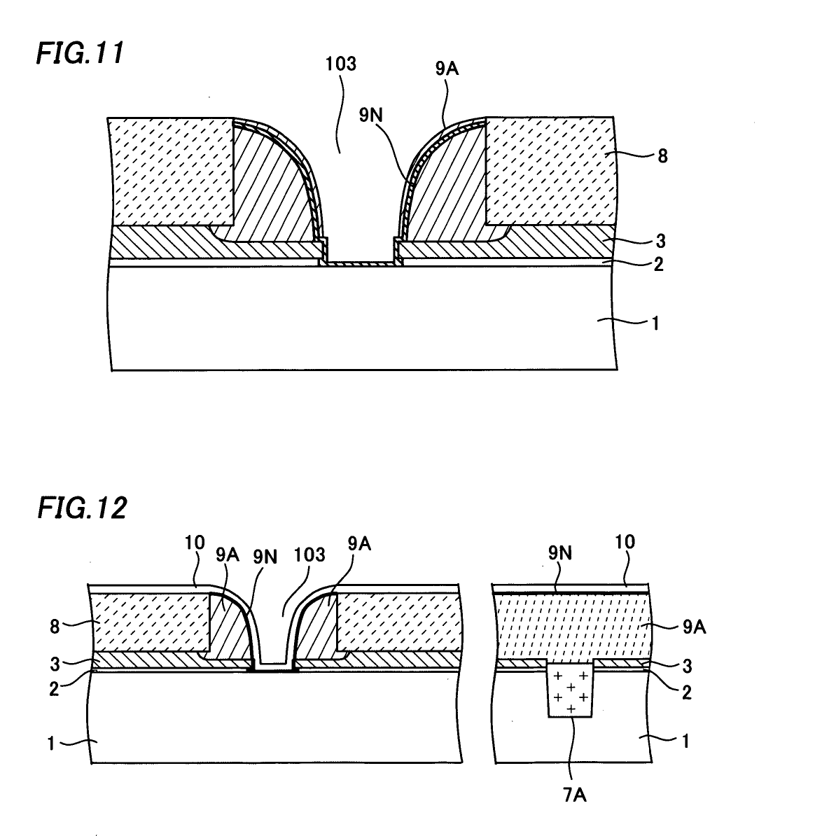

FIGS. 2 to 19 are cross sectional views showing the manufacturing method of the semiconductor device of this embodiment along with the cross sectional lines of X-X and Y-Y in FIG. 1. The left side figures in FIGS. 2-19 show the cross section along with the X-X line, and the right side figures in FIGS. 2-19 show the cross section along with the Y-Y line. Only the cross sectional view along with the X-X line is seen in FIG. 11.

The gate insulation film 2, which is an silicon oxide film (SiO₂ film) of the thickness of about 10 nm, is formed on the semiconductor substrate 1, which is a P type silicon substrate, through the thermal oxidation, as shown in FIG. 2. Then, a first polysilicon film 3 with the thickness of about 50 nm and a first silicon nitride film 4 with thickness of 120 nm are disposed on the gate insulation film 2 through the CVD method.

A photo resist layer 5 with an opening 5H is formed on the first silicon nitride film 4, as shown in FIG. 3. A trench 6 is formed by performing etching to the first silicon nitride film 4, the first polysilicon film 3, the gate insulation film 2, and further to the semiconductor substrate 1 using the photo resist layer 5 as a mask. The depth of the trench 6 is ideally less than 1 μm.

A silicon oxide film (for example, a TEOS film) is disposed on entire surface including the trench 6 through CVD method, as shown in FIG. 4. Then the surface of the silicon oxide film is polished using CMP method (chemical mechanical polishing method). The silicon nitride film works as the film for detecting the timing to stop CMP. That is, CMP is stopped when the exposure of the silicon nitride film 4 is chemically detected. The STI layer 7A, which is an element separation film selectively buried in the trench 6, is formed in this manner. Then, the first silicon nitride film 4 is removed by using chemicals such as hot phosphate as shown in FIG. 5. The STI layer 7A can be formed other methods than the method described above.

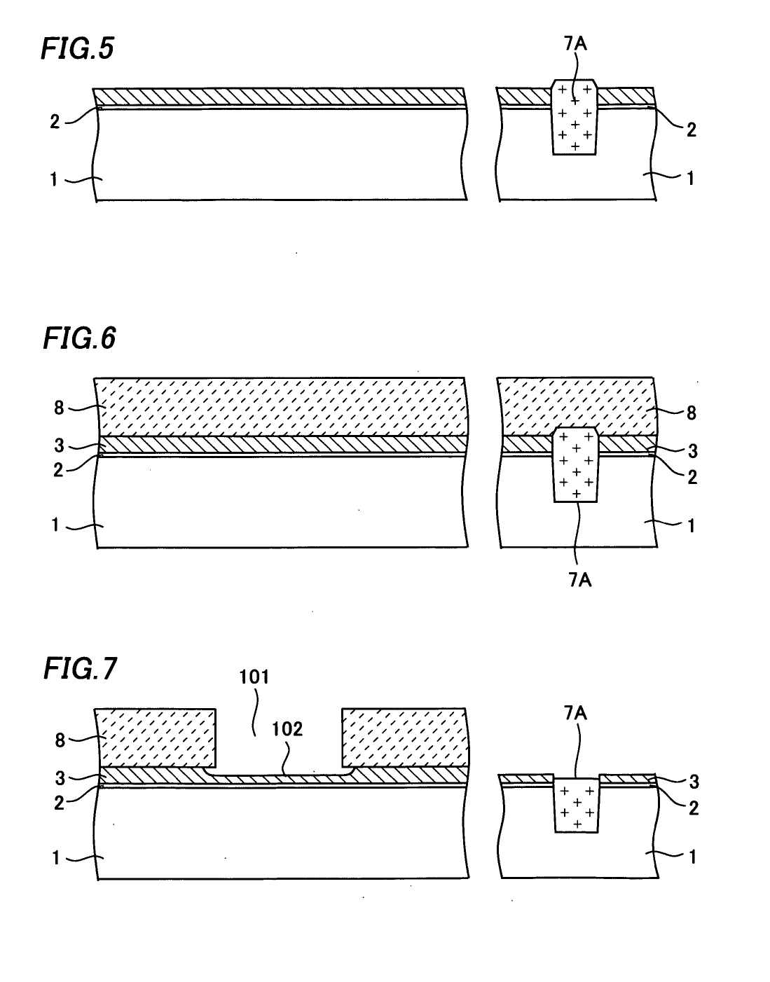

A thick second silicon nitride film 8 with the thickness of about 400 nm is formed as a mask layer through CVD method on the entire surface of the first polysilicon film 3 including the STI layer 7A, as shown in FIG. 6. Then, a first opening 101 is formed at the area where the floating gate 3A will be formed by selectively etching the silicon nitride film 8 in that area, as shown in FIG. 7. Isotropic etching is performed on the surface of the first polysilicon film 3 using the silicon nitride film 8 with the opening 101 as a mask. This process creates a shallow concave portion 102 on the surface of the first polysilicon film 3. Also, the isotropic etching creates an under cut portion beneath the edge of the second silicon nitride film 8. The surface of the STI layer 7A is partially etched.

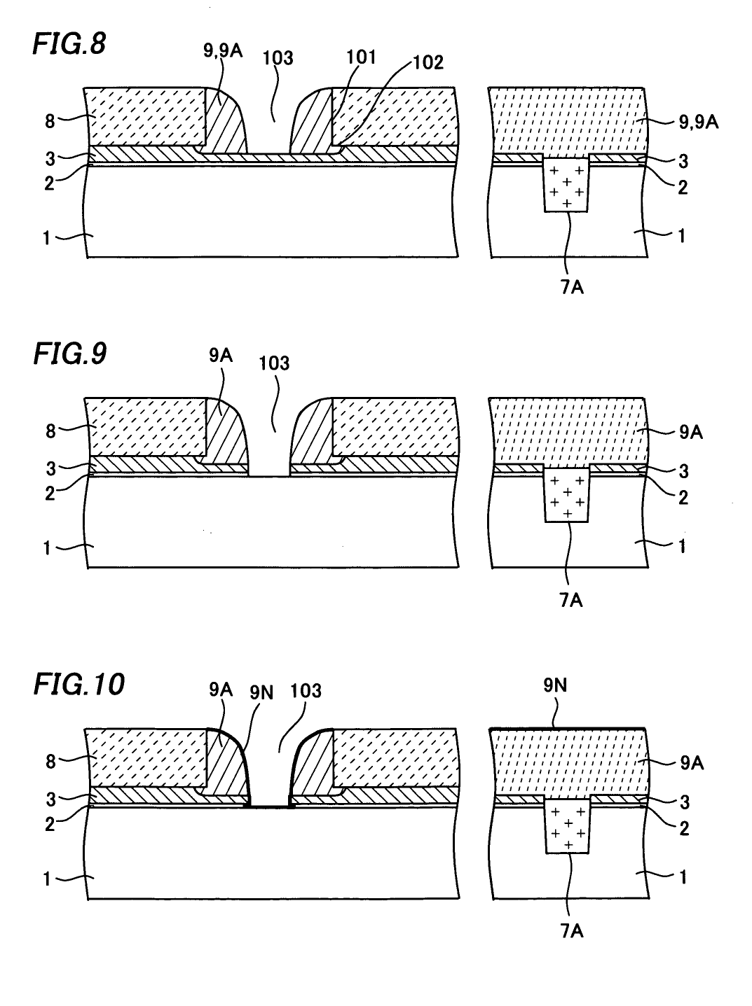

A first silicon oxide film 9 is disposed on the entire surface of the second silicon nitride film 8 including the first opening 101, the concave portion 102, the STI layer 7A through CVD method, as shown in FIG. 8. Then, etch back is performed by anisotropic etching. The etch-back is performed until the surface of the second silicon nitride film 8 is exposed. As a result, the spacer film 9A, made of a silicon oxide film is formed at the side-wall of the second silicon nitride film 8. Then, etching is performed on the first polysilicon film 3 and the gate insulation film 2 using the spacer film 9A as a mask, as shown in FIG. 9, forming a second opening 103 that exposes the surface of the semiconductor substrate 1.

Next, a first oxidation prevention layer 9N, which is made of a nitrogen containing layer for preventing the diffusion of the oxidation seeds described later, is disposed by a predetermined anneal processing on the spacer film 9A, on the edge of the first polysilicon film 3 inside the second opening 103, and on the surface of the semiconductor substrate 1 exposed by the opening 103, as shown in FIG. 10. The first anneal processing described above is ideally performed in ammonia (NH₃) gas atmosphere through the RTA (ramp thermal anneal) method with the temperature of about 900° C. for 30 seconds.

When the first anneal processing is performed in other atmosphere, such as carbon monoxide (NO) gas, the oxidation prevention layer, which is made of a nitrogen containing layer, may be formed only on the surface of the spacer film 9A. In such a case, most of the oxidation prevention layer is removed as part of the spacer film 9A when the spacer film 9A is etched in the subsequent process.

However, the first anneal processing of this embodiment is performed in the ammonia (NH₃) gas atmosphere, which has a high nitrogen content. Therefore, the nitrogen atoms in the ammonia (NH₃) gas easily penetrate inside the spacer film 9A. This enables the formation of the first oxidation prevention layer 9N not on the surface, but deeply inside the spacer film 9A. Therefore, a part of the first oxidation prevention layer 9N can remain on the spacer film 9A after the etching to the spacer film 9A removes the surface of the spacer film 9A, as shown in FIG. 11. Also, the first oxidation prevention layer 9N is formed on the surface of edge of the gate insulation film 2 on the bottom of the opening 103.

The first oxidation prevention layer 9N prevents the diffusion of oxidation seeds to the polysilicon film 3 (later becomes the floating gate 3A) during the thermal oxidation treatment described later.

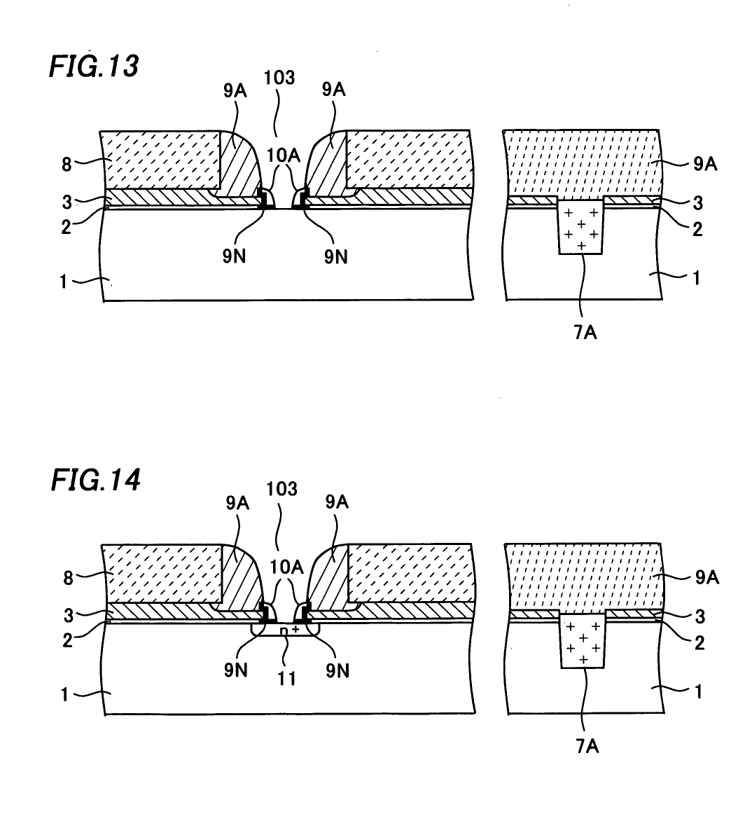

A second silicon oxide film 10 with the thickness of 30 nm is disposed through CVD method on the second silicon nitride film 8, the spacer film 9A, the first oxidation prevention layer 9N (formed on the edge of the first polysilicon film 3 and the semiconductor substrate 1) inside the second opening 103, as shown in FIG. 12. Etch back is performed on the second silicon oxide film 10 through the anisotropic etching to form a side cap 10A, as shown in FIG. 13. The etch-back also removes a part of the oxidation prevention layer 9N, which is formed on a part of the spacer film 9A and the upper side of the STI layer 7A.

Next, an n+ type impurity (for example, arsenic) is injected through ion-injection using the spacer film 9A and the second silicon nitride film 8 as a mask to the semiconductor substrate 1, forming an n+ type source region 11 in a self-aligned manner, as shown in FIG. 14.

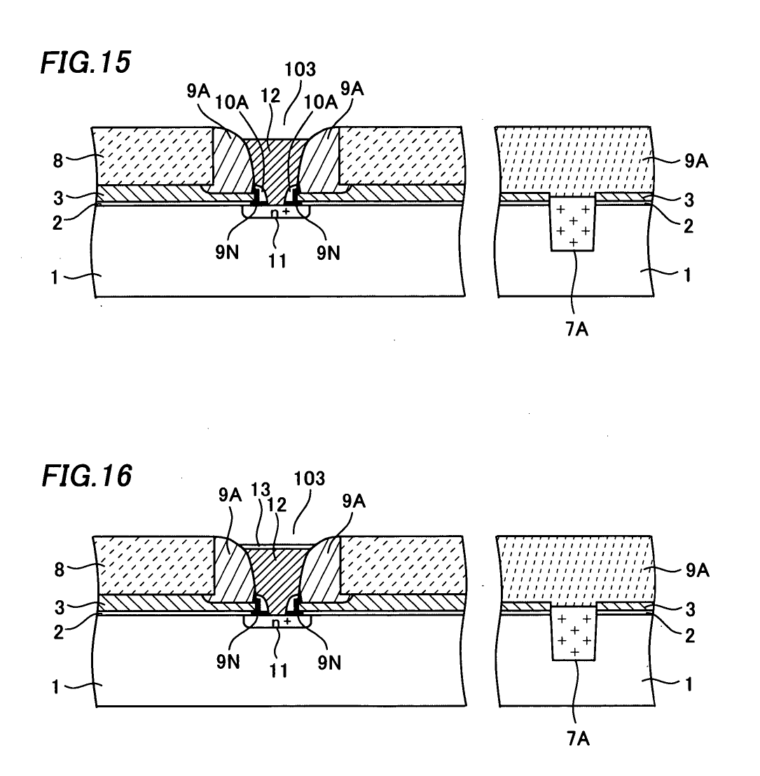

Then, a source line 12 making contact with the source region 11 is formed in the second opening 103 surrounded with the spacer film 9A and the side cap film 10A, as shown in FIG. 15. The source line 12 is formed by disposing, for example, a polysilicon film on the entire surface through the CVD method and performing etching process to remove the polysilicon film located areas other than inside of the second opening 103.

Next, a source line cap film 13, which is made of a silicon oxide film and which covers the upper surface of the source line 12, is formed on the source line 12 through thermal oxidation treatment, as shown in FIG. 16.

Oxidation seeds try to diffuse to the edge of the first polysilicon film 3 inside the second opening 103 through the spacer film 9A during the thermal oxidation treatment. However, the spacer film 9A, the edge of the first polysilicon film 3 inside the second opening 103, and the gate insulation film 2 are all covered with the first oxidation prevention layer 9N formed in the previous process. The first oxidation prevention layer 9N prevents the diffusion of the oxidation seeds to the first polysilicon film 3. Therefore, the oxidation of the edge of the first polysilicon film 3 can be prevented as much as possible.

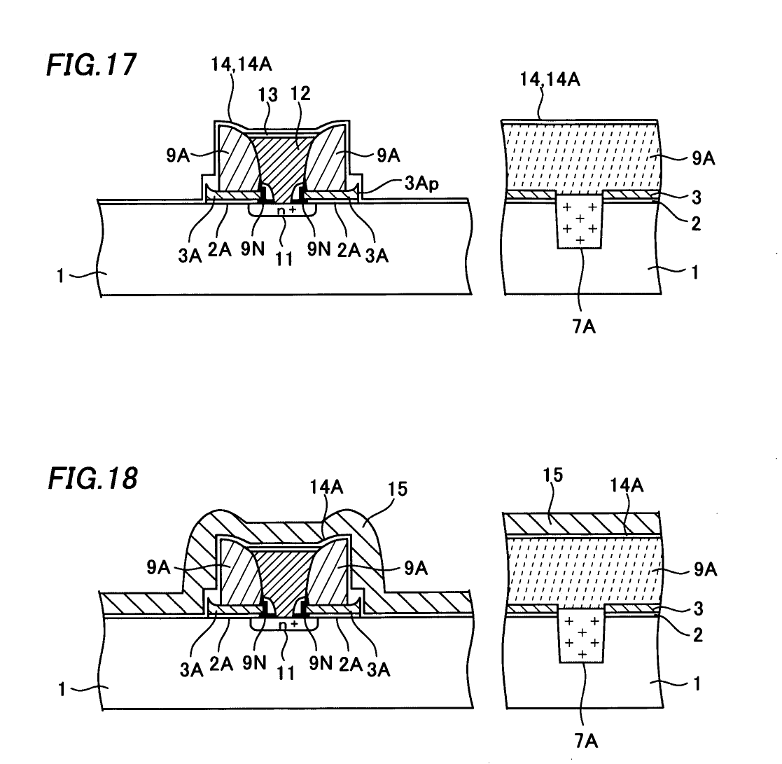

Then, the second silicon nitride film 8 is removed by chemicals such as hot phosphate, and anisotropic etching is performed on the first polysilicon film 3 and the gate insulation film using the spacer film 9A as a mask, configuring a pair of floating gates 3A, 3A, as shown in FIG. 17. The floating gates 3A, 3A are formed in a self-aligned manner to the spacer film 9A. A peak portion 3Ap is formed at one end of the floating gates 3A, 3A, where the side cap 10A has not been formed. It is because the edge of the concave portion 102 curves upwards due to the isotropic etching during its formation.

A tunnel insulating film 14A is further formed by disposing a silicon oxide film 14 with the thickness of about 20 nm through CVD method on the entire surface of the semiconductor substrate including on the spacer film 9A, source line cap film 13, and floating gate 13A. The tunnel insulation film 14 is formed to cover the side surface and a part of the upper surface of the floating gate 3A.

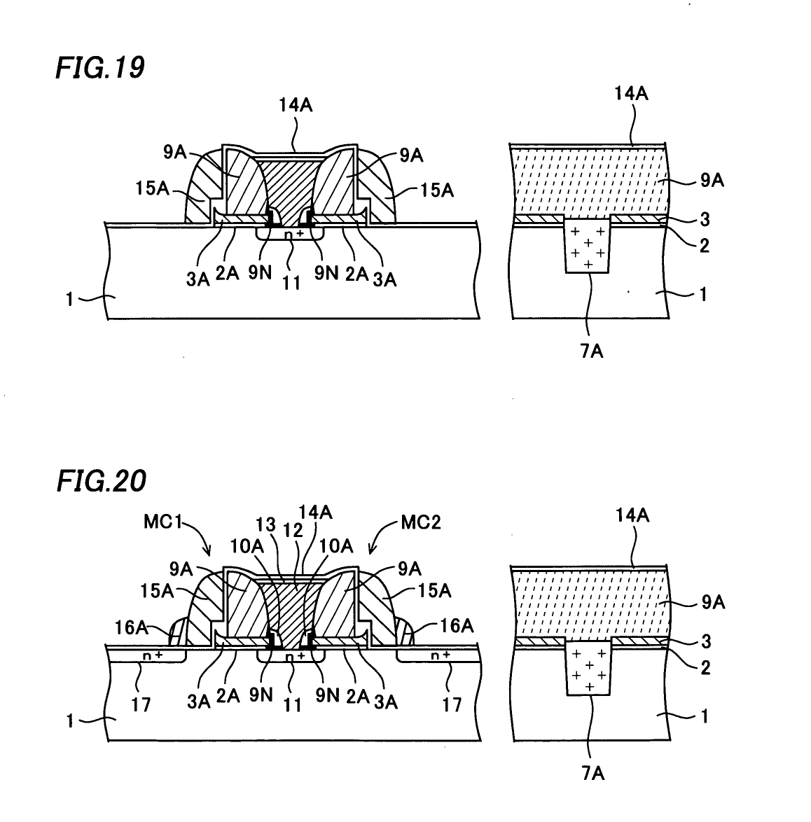

Next, a second polysilicon film 15 with the thickness of about 200 nm is disposed through CVD method on the entire surface of the tunnel insulating film 14, as shown in FIG. 18. A control gate 15A is formed by performing etch back of the anisotropic etching processing to the second polysilicon film 15, as shown in FIG. 19. The control gate 15A is formed in a self-aligned manner at the side of the spacer film 9A on the semiconductor substrate 1 with the tunnel insulation film 14A between them.

Then, a mini-spacer film 16A is formed at the lower side of the control gate 15A, as shown in FIG. 20. The mini-spacer film 16A is formed by disposing a silicon oxide film through CVD method and performing etch back on the film. An n type impurity, such as arsenic (As) is injected through ion-injection to the semiconductor substrate 1 using the control gate 15A as a mask, forming n+ type drain regions 17, 17 in a self aligned manner to the control gate 15A. The surface of the semiconductor substrate 1 between the source region 11 and the drain region 17 becomes a channel region.

A pair of memory cells MC1 and MC2, symmetrically disposed with the source region 11 in the center is formed on the semiconductor substrate 1. The memory cells MC3, MC4 in FIG. 1 as well as other memory cells not shown in figures are also formed through the same manufacturing processes.

The first oxidation prevention layer 9N made of a nitrogen containing layer that can prevent the diffusion of the oxidation seed is formed at the edge of the spacer film 9A and the floating gate 3A in this embodiment. The diffusion of the oxidation seed to the floating gate 3A, which was observed in the conventional semiconductor device, during the formation of the source line cap film 13 through the thermal oxidation treatment to the source line 12 can be prevented because of the first oxidation prevention layer 9N. Therefore, the oxidation of a part of the floating gate 3A can be prevented as much as possible.

The deterioration of the coupling property, which may cause the malfunction of the memory cell can be reduced, improving the reliability and the yield rate of the memory cell.

The first oxidation prevention layer 9N, once formed on the STI layer 7A, is soon removed during the etching of the second silicon oxide film 10 at the next process. Therefore, the oxidation seed from the thermal oxidation treatment diffuses to the border between the STI layer 7A and the first polysilicon film 3 in some cases. This causes the oxidation of the first polysilicon film 3 near the STI layer 7A. The second embodiment of the invention described below is directed to solving the problem of the diffusion of the oxidation seed near the STI layer.

Next, the manufacturing method of the second embodiment of the semiconductor device of this invention will be explained by referring to figures.

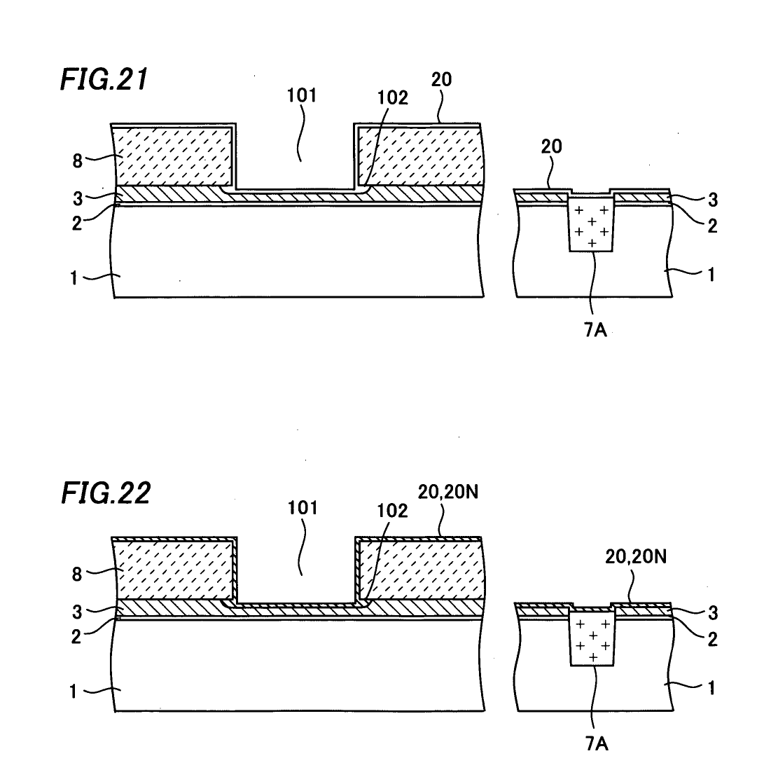

FIGS. 21 to 29 are cross sectional views showing the semiconductor device and its manufacturing method of this invention. The plan view for the second embodiment is the same as that of the first embodiment shown in FIG. 1. The left side figures in FIGS. 21 to 29 show the cross section along with the X-X line, and the right side figures in FIGS. 21 to 29 show the cross section along with the Y-Y line. The components that are identical to those in FIG. 1 have the same numerical reference as in FIG. 1.

The manufacturing processes from the beginning till the formation of the opening 101 and the concave portion 102 in the second silicon nitride film 8 on the semiconductor substrate 1 corresponding to FIGS. 2 to 7 of the first embodiment are repeated in this second embodiment of the semiconductor device of this invention. The manufacturing processes following the process shown in FIG. 7 will be explained below.

A fourth silicon oxide film 20 with the thickness of 32 nm is disposed, for example, through the CVD method, on the second silicon nitride film 8 including inside the opening 101 and the concave portion 102 after the process shown in FIG. 7, as shown in FIG. 21. Then, a second oxidation prevention layer 20N made of the nitrogen containing layer that can prevent the diffusion of the oxidation seed is formed by performing the second anneal processing in a predetermined manner to the fourth silicon oxide film 20, as shown in FIG. 22.

The second anneal processing is preferably done in the same manner as in the first anneal processing of the first embodiment. That is, it is ideally performed in ammonia (NH₃) gas atmosphere using ramp thermal anneal method with the temperature of about 900° C. for 30 second.

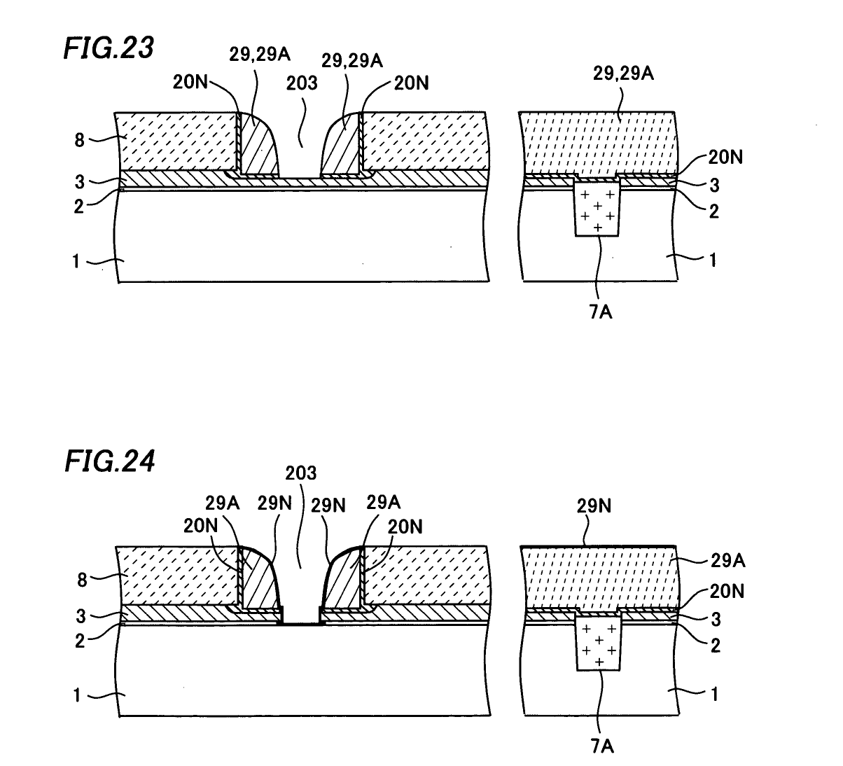

A fifth silicon oxide film 29 is disposed through CVD method on the fourth silicon oxide film 20, including the first opening 101 and the STI layer 7A, as shown in FIG. 23. Etch back is performed on the fifth silicon oxide film 29 through anisotropic etching. The etch-back is performed until the surface of the second nitride film 8 is exposed. As a result, a spacer film 29A made of the fifth silicon oxide film 29 is formed at the side-wall of the second silicon nitride film 8. Then, etching is performed to the first polysilicon film 3 and the gate insulation film 2 until the surface of the semiconductor substrate 1 is exposed using the spacer film 29A as a mask. The second opening 203 is formed in this manner.

A third anneal processing is performed in the same manner as in the first anneal processing of the first embodiment, as shown in FIG. 24. Then, a third oxidation prevention layer 29N that is the same as the first oxidation prevention layer 9N is disposed on the spacer film 29A, on the edge of the first polysilicon film 3 inside the second opening 203, and on the surface of the semiconductor substrate 1 exposed by the second opening 203.

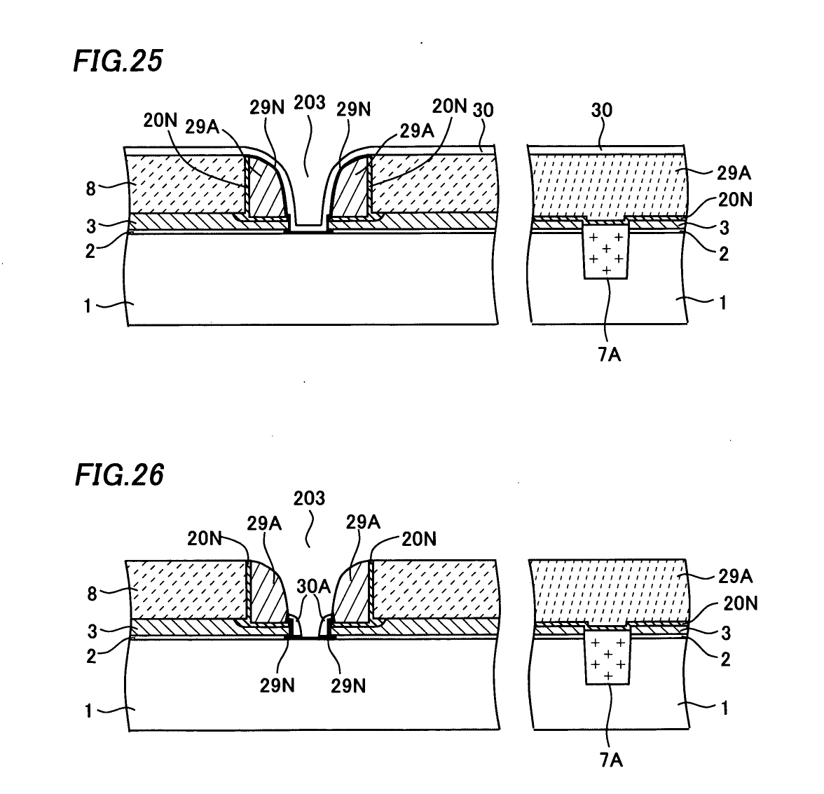

The sixth silicon oxide film 30, corresponding to the second silicon oxide film 10 in the first embodiment is disposed on the second silicon nitride film 8, the spacer film 9A, the second opening 103 and the second oxidation prevention layer 20N (formed on the edge of the first polysilicon film 3 and the semiconductor substrate 1) inside the second opening 103, as shown in FIG. 25. Etch back is performed on the sixth silicon oxide film 30 through anisotropic etching to form a side cap 30A, as shown in FIG. 26.

The etch-back processing in this embodiment differs from the etch-back performed on the second silicon oxide film 10 in the first embodiment (refers to FIG. 13). That is, the etch-back of this embodiment does not remove the third oxidation prevention layer 29N formed on the STI layer 7A and the first polysilicon film 3.

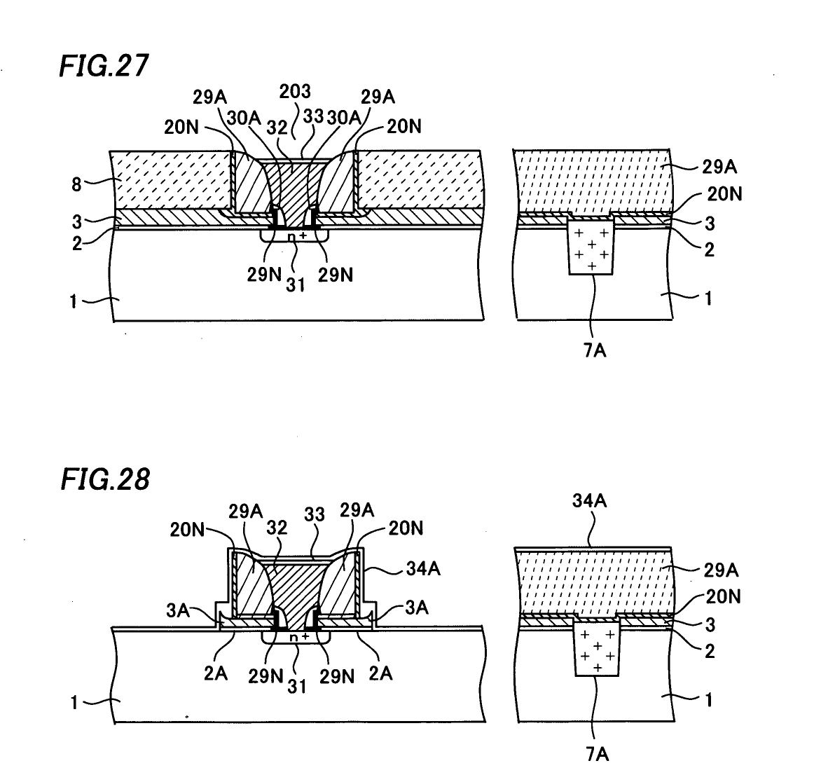

Next, an n+ type source region 31 is formed in a self-aligned manner, as shown in FIG. 27. Then, a source line 32 making contact with the source region 31 is formed in the second opening 203 surrounded with the spacer film 29A and the side cap film 30A. The source line 32 is formed in the same manner as that of the source line 12 of the first embodiment. A source line cap film 33, which is made of a silicon oxide film and which covers the upper surface of the source line 32, is formed on the source line 32 through thermal oxidation.

The second oxidation prevention layer 20N and the third oxidation layer 29N cover the first silicon film 3. And, the second oxidation prevention layer 20N covers the STI layer 7A. Therefore, the diffusion of the oxidation seed to the first polysilicon film 3 through the STI layer 7A can be prevented as much as possible.

Then, the second silicon nitride film 8 is removed by chemicals such as hot phosphate, and anisotropic etching is performed on the first polysilicon film 3 and the gate insulation film using the spacer film 9A as a mask, configuring a pair of floating gates 3A, 3A, as in the first embodiment, as shown in FIG. 28. A tunnel insulation film 34A is formed by disposing a silicon oxide film on the entire surface of the semiconductor substrate 1 including on the spacer film 29A, source line cap film 33 and the floating gate 3A.

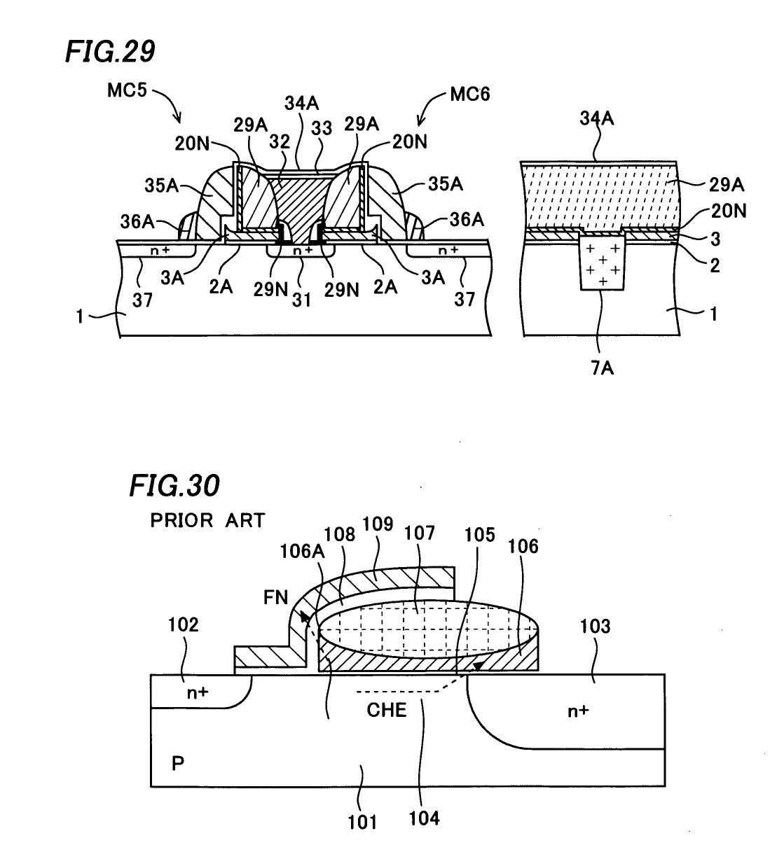

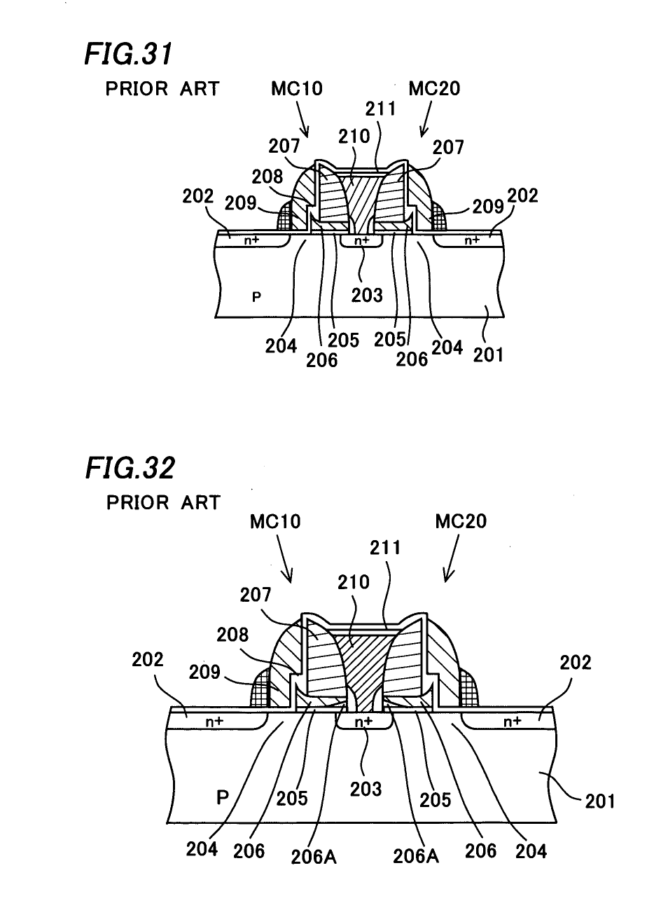

A control gate 35A is formed by performing etch back of anisotropic etching processing to the polysilicon film disposed on the entire surface of the tunnel insulation film 34A, like the control gate 15A of the first embodiment is formed, as shown in FIG. 29. Then, a mini-spacer film 36A is formed at the lower side of the control gate 35A. An n type impurity, such as arsenic (As) is injected through ion-injection to the semiconductor substrate 1 using the control gate 35A as a mask, forming n+ type drain regions 37, 37 in a self aligned manner to the control gate 35A. The surface of the semiconductor substrate 1 between the source region 31 and the drain region 37 becomes a channel region.

A pair of memory cells MC5 and MC6, symmetrically disposed with the source region 31 in the center is formed on the semiconductor substrate 1. The other memory cells not shown in figures are also formed through the same manufacturing process.

In this embodiment, the second oxidation prevention layer 20N and the third oxidation layer 29N cover the upper surface of the first polysilicon film 3 and the edge of the first polysilicon film 3, respectively. In addition, the second oxidation prevention layer 20N covers the STI layer 7A. Therefore, the prevention of the diffusion of the oxidation seed is even improved in this embodiment compared to the first embodiment. The oxidation of the floating gate is prevented as much as possible.

What is claimed is:

1. A method of manufacturing a semiconductor device, comprising:
providing a semiconductor substrate comprising a first insulation film formed on a surface thereof;
forming a first semiconductor layer on the first insulation film;
forming a mask layer on the first semiconductor layer, the mask layer having an opening to expose part of the first semiconductor layer;
performing an etching on the exposed first semiconductor layer using the mask layer as an etching mask;
forming a spacer on a sidewall of the opening;
etching the first semiconductor layer and the first insulation film using the spacer as an etching mask to expose part of the semiconductor substrate;
forming a first oxidation prevention layer containing nitrogen along a sidewall of the spacer and an edge of the etched first semiconductor layer;
forming a source line in the opening;
forming a cap film on the source line by performing an oxidation on the source line;
forming a floating gate made of the first semiconductor layer by removing at least part of the mask layer and part of the first semiconductor layer;
forming a tunnel insulating film on the spacer, the source cap film and the floating gate;
forming a second semiconductor layer on the tunnel insulating film; and
forming a control gate by removing part of the second semiconductor layer.

2. The method of claim 1, wherein each of the first and second semiconductor layers is made of a polysilicon film.

3. The method of claim 1, wherein the spacer is made of a silicon oxide, and the forming of the first oxidation prevention layer comprises annealing the spacer in an ammonia atmosphere.

4. The method of claim 1, wherein the forming of the first oxidation prevention layer comprises annealing the spacer in an atmosphere containing nitrogen atoms.

5. The method of claim 1, further comprising forming an element separation layer on part of the semiconductor substrate after the first semiconductor layer is formed, forming a second insulation film on a sidewall of the opening of the mask layer, on the mask layer and on the element separation layer after the etching on the exposed first semiconductor layer is performed, and forming a second oxidation prevention layer containing nitrogen by introducing nitrogen atoms into the second insulation film.

6. The method of claim 5, wherein the second insulation film is made of a silicon oxide, and the introduction of nitrogen atoms comprises annealing the second insulation film in an ammonia atmosphere.

7. The method of claim 5, wherein the introduction of nitrogen atoms comprises annealing the second insulation film in an atmosphere containing nitrogen atoms.
